(19) United States
(12) Patent Application Publication
(10) Pub. No.: US 2005/0215044 A1
(43) Pub. Date: Sep. 29, 2005

(54) METHOD FOR FORMING PHOTORESIST LAYER ON SUBSRTATE AND BUMPING PROCESS USING THE SAME

(76) Inventor: Min-Lung Huang, Kaohsiung (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/907,156

(22) Filed: Mar. 23, 2005

(30) Foreign Application Priority Data
Mar. 26, 2004 (TW) 93108236

(51) Int. Cl. H01L 21/44; H01L 21/469

(52) U.S. Cl. 438/614; 438/615; 438/780

(57) ABSTRACT

A method for forming a photoresist layer on a substrate to improve the joining of the photoresist layer and the substrate is provided. For a bumping process using the method, a liquid is used to react with the photoresist layer to form a combination layer of good fluidity between the photoresist layer and the passivation layer on the substrate. The combination layer fills the pits of the passivation layer to improve the joining of the photoresist layer and the passivation layer. Therefore, when the solder material is filled into the openings, no solder material stays between the photoresist layer and the passivation layer, so as to avoid solder bridging between the two adjacent pads.

### CROSS-REFERENCE TO RELATED APPLICATION

This application claims the priority benefit of Taiwan application serial no. 93108236, filed on Mar. 26, 2004.

### BACKGROUND OF THE INVENTION

1. Field of the Invention

The present invention generally relates to a method for forming a photoresist layer on a substrate. More particularly, the present invention relates to a method for forming a photoresist layer on a substrate and a bumping process using the same, which improves the joining between the photoresist layer and the substrate. The present invention applies two photoresist layers that are made of different viscosity coefficients of material on the substrate so that the joining between the photoresist layers and the substrate is improved.

2. Description of Related Art

Following the rapid growth of electric technologies, the performance of electric devices becomes better, and the sizes of the electric devices become smaller. In order to serve the trends of the electric devices, including high speed, multiple functions and lightness, the integrated circuit (IC) packaging technology needs to improve, being minimized, high density and more compact. Accordingly, for packaging IC chips with high pin counts, high density IC chip packages such as ball grid array (BGA) packages, chip-scale packages (CSP), flip chip (FC) packages and multi-chip module (MCM) packages have been developed. The density of the IC package refers to the pin numbers of the package in an unit area. Since the bumps can shorten the signal transmission path to increase the speed of signal transmission, the bumps have been widely used in the field of high density chip package.

FIGS. 1A through 1F are schematic cross-sectional views showing a conventional bumping process. Referring to FIG.1A, a wafer 100 is provided. The wafer 100 includes a plurality of pads 102 on the surface of the wafer 100. The wafer 100 further includes a passivation layer 106, which covers the surface of the wafer 100 and exposes the pads 102. In addition, an under bump metallurgy (UBM) layer 104 is disposed on the exposed surface of each pad 102 and on portions of the passivation layer 106.

Referring to FIG. 1B, a photoresist layer 108 is formed over the wafer 100. Referring to FIG. 1C, a plurality of openings 108a are formed in the photoresist layer 108 corresponding to the positions of the pads 102 after exposure and development processes, for example. The UBM layers 104 on the pads 102 are exposed by the openings 108a, respectively.

Referring to FIG. 1D, a solder material is filled into each of the opening 108a by, for example, stencil printing, to form a plurality of solder blocks 110 on the UBM layers 104 respectively. Then, the photoresist layer 108 is removed. Referring to FIG. 1F, a reflow step is performed so that the solder blocks 110 slightly melt, and turn into a ball shape. After the reflow step, the solder blocks 110 solidify and become spherical bumps 110a on the UBM layers 104 respectively.

In the above-mentioned bumping process, the surface of the passivation layer generally is not an ideal surface. When the photoresist layer is formed on the surface of the passivation layer, the photoresist layer cannot closely attach to the passivation layer and gaps may exist between the photoresist layer and the passivation layer. However, as the integration of the IC chip package keeps increasing, the pitch of neighbor two pads becomes shorter and shorter. When the solder material is filled in the openings, the solder material may flow into the gaps and the neighbor pads may be mistakenly connected through solder bridging of the adjacent solder blocks.

FIG. 1G is an enlarged partial cross sectional view of FIG. 1D. Referring to FIG. 1G, the above-mentioned gaps 106a exist between the passivation layer 106 and the photoresist layer 108. The solder material is filled into the openings 108a to form the solder blocks 110, but the solder material can also be filled into the gaps 106a. Therefore, a portion of the solder material accumulated at the gaps 106a may cause solder bridging established between the neighbor two pads 102.

### SUMMARY OF THE INVENTION

Accordingly, one purpose of the present invention is to provide a bumping process for preventing solder bridging between two neighboring pads.

Another purpose of the present invention is to provide a method for forming a photoresist layer on a substrate for improving the joining between the photoresist layer and the substrate.

In accordance with the purposes of the invention and other purposes, a bumping process is provided. A wafer having a plurality of pads and a passivation layer thereon is provided, and the passivation layer protects the wafer and exposes the pads. Then, a plurality of metal layers are formed on the pads of the wafer, and each of the metal layers covers each of the pads respectively. After a liquid is applied over the wafer, a photoresist layer (or film) is formed over the wafer and covers the pads and passivation layer. The photoresist layer can react with the liquid to form a combination layer with fluidity. Then, the photoresist layer is patterned to form a plurality of openings that expose the metal layers respectively. After that, the solder material is filled into the opening to form a plurality of solder blocks. Finally, the photoresist layer is removed.

According to an embodiment of the present invention, the liquid at least comprises deionized water or chemical solvents.

According to an embodiment of the present invention, the solder material is filled into the openings by electroplating or printing.

According to an embodiment of the present invention, after the removing of the photoresist layer, the process further comprising performing a reflow step to the solder blocks to form a plurality of bumps on the metal layers respectively.

According to the present invention, the photoresist layer reacts with a liquid such that a combination layer of good fluidity is formed between the photoresist layer and the passivation. The combination layer of good fluidity can cover the pits of the passivation layer and properly join the photoresist layer with the passivation layer. Hence, during the filling of the solder material into the openings, no solder material will be inserted between the photoresist layer and the passivation layer, thus avoid solder bridging between two adjacent pads.

In accordance with the purposes of the invention and other purposes, a method for forming a photoresist layer on a substrate is further provided. At first, a liquid is applied over the wafer, and then, a photoresist layer (or film) is formed over the wafer.

According to an embodiment of the present invention, the liquid at least comprises deionized water or chemical solvents.

According to the above mentioned, the method of the present invention may be applied in the bumping process to improve the joining between the photoresist layer and the substrate, and provides proper attachment between the photoresist layer made of various materials and the substrate.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A through 1F are schematic cross-sectional views showing a conventional bumping process.

FIG. 1G is an enlarged partial cross sectional view of FIG. 1D.

FIGS. 2A through 2G are schematic cross-sectional views showing a bumping process according to a preferred embodiment of this invention.

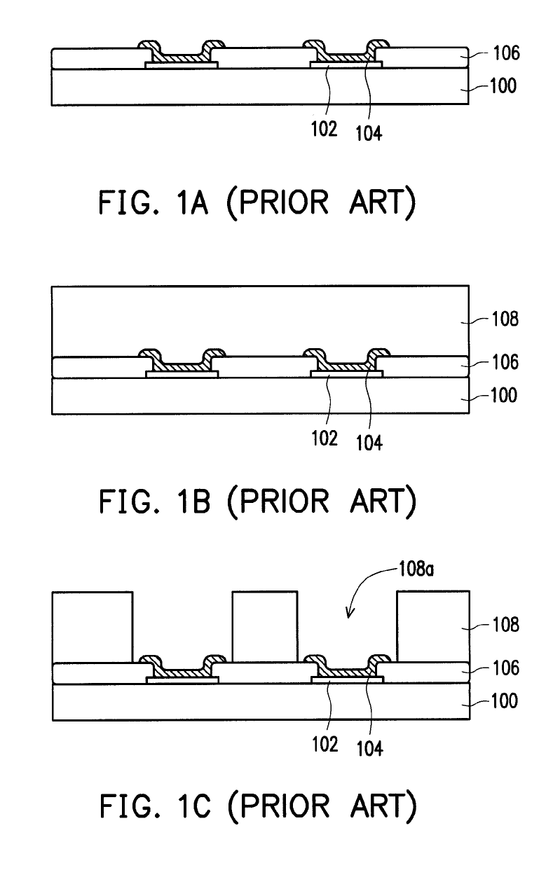

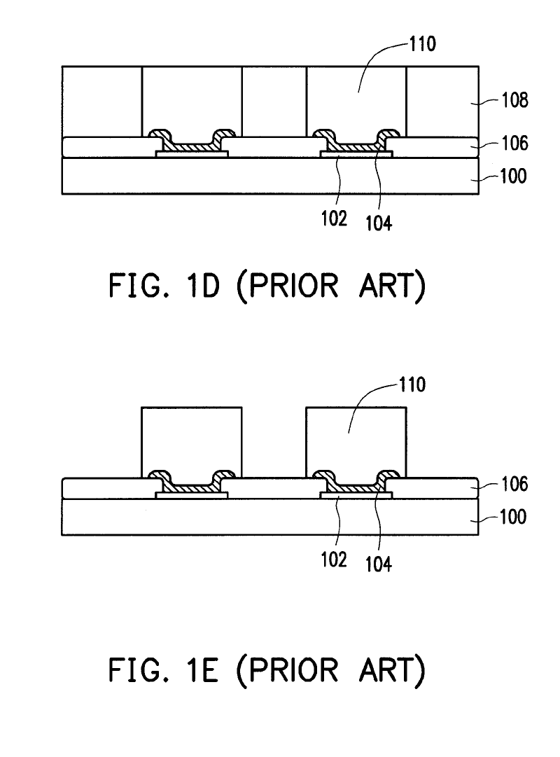

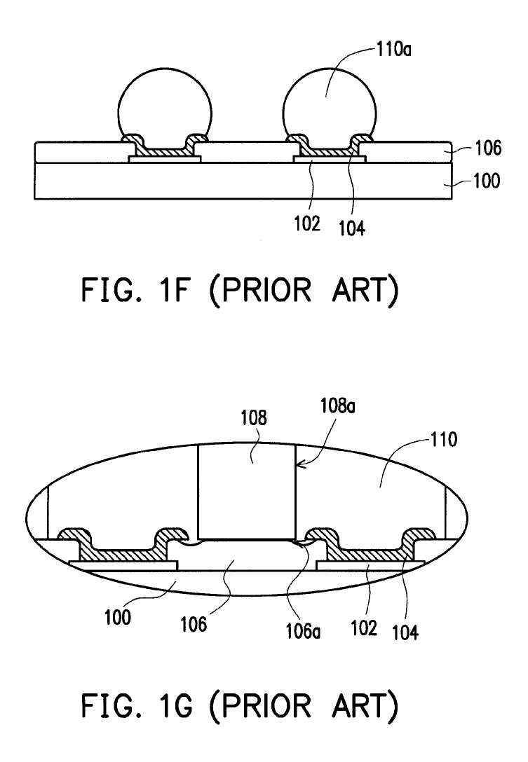

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

In the embodiments of the present invention, a method for forming a photoresist layer on a substrate and a bumping process using the same are illustrated, which can prevent solder bridging between two neighboring pads.

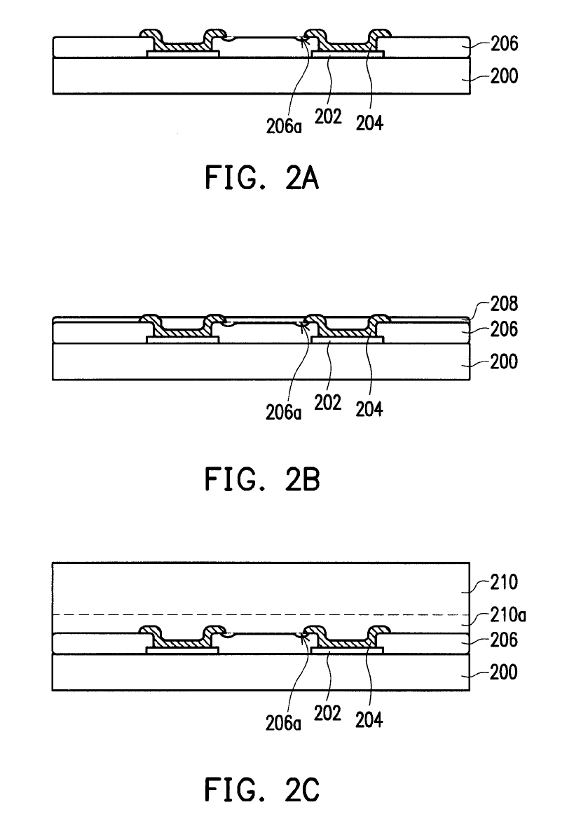

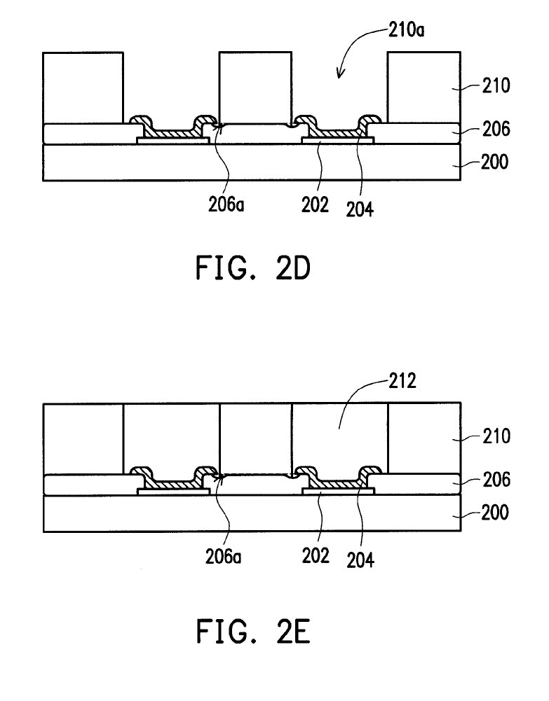

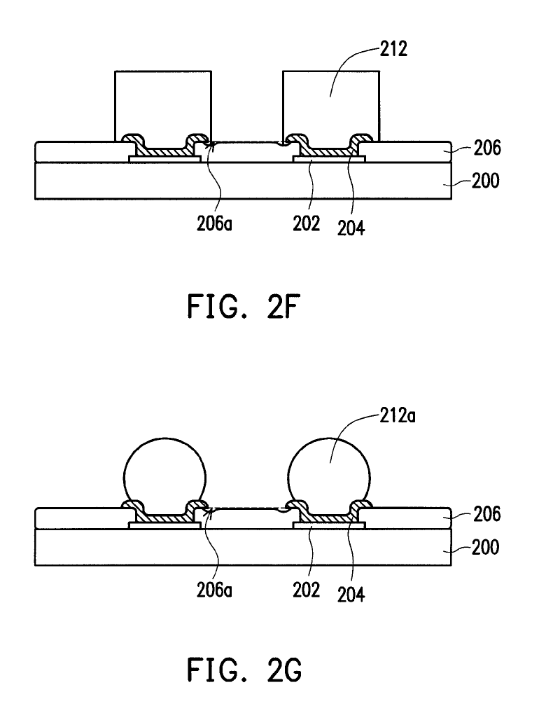

FIGS. 2A through 2G are schematic cross-sectional views showing a bumping process according to a preferred embodiment of this invention. Referring to FIG. 2A, a wafer 200 having a plurality of pads 202 on the surface of the wafer 200 is provided. The wafer 200 includes a passivation layer 206, which covers the surface of the wafer 200 and exposes the pads 202. In addition, the wafer 200 includes a plurality of UBM layers 204. Each of the UBM layers 204 is deposited on the surface of each exposed pad 202 and on portions of the passivation layer 206 surrounding the pad 202.

Referring to FIG. 2B, since the surface of the passivation layer 206 may not be an ideal surface for joining the subsequently formed photoresist layer 210 (shown in FIG. 2C), gaps 206a might exist between the passivation layer 206 and the photoresist layer 210 if the photoresist layer 210 is directly formed on the passivation layer 206. As discussed previously, the existing gaps 206a may lead to solder bridging in the subsequent processes. Hence, in order to solve the aforementioned issues and properly join the photoresist layer 210 (FIG. 2C) to the passivation layer 206, a liquid (or a solution) 208 comprising deionized water, chemical solvents or etc. is applied over the passivation layer 206 by either spraying or coating, for example.

Referring to FIG. 2C, a photoresist layer 210 is formed over the wafer 200 by spin-coating or dry-film attachment, for example, and covers the UBM layer 204 and the passivation layer 206. In the mean time, the liquid 208 reacts with the photoresist layer 210 and results in a combination layer 210a having good fluidity between passivation layer 206 and the photoresist layer 210. Since the combination layer 210a has a better fluidity than that of the photoresist layer 210, the combination layer 210a can fill the gaps 206a on the passivation layer 206.

Referring to FIG. 2D, the photoresist layer 210 is patterned to form a plurality of openings 210a by exposure and development processes, for example. The positions of the openings 210a respectively correspond to the positions of the UBM layers 204 on the pads.

Referring to FIG. 2E, a solder material is filled into the openings 210a to form a plurality of solder blocks 212, and then the photoresist layer 210 is removed shown in FIG. 2F.

Referring to FIG. 2G, a reflow step is performed on the solder blocks 212 to slightly melt the solder blocks 212. Because of the cohesive force, the solder block 212 turns into a spherical shape during the reflow step. After the reflow step and the melted solder blocks 212 solidify, a plurality of spherical bumps 212a are formed.

In summary, according to the present invention, a liquid reacting with the photoresist layer is used, so that a combination layer of good fluidity is formed between the photoresist layer and the passivation layer. The combination layer can fill the pits or gaps of the passivation layer (i.e. the gaps between the photoresist layer and the passivation layer if the photoresist layer is directly formed on the passivation layer). Therefore, when the solder material is filled into the openings, the solder material will not be filled into the gaps and no solder bridging occurs between the neighboring two pads.

The above-mentioned embodiment only employs a bumping process to illustrate the application of the method for forming a photoresist layer on a substrate. However, the substrate is not limited to a wafer, but can be other kind of substrate, and the material of the photoresist layer should be selected depending on the application process.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A bumping process, comprising:
providing a wafer having a plurality of pads and a passivation layer thereon, and wherein the passivation layer protects the wafer and exposes the pads;
forming a plurality of metal layers over the wafer, wherein the metal layers respectively cover the pads;
providing a liquid over the wafer;
forming a photoresist layer over the wafer, covering the pads and passivation layer, wherein the photoresist layer reacts with the liquid to form a fluid combination layer between the wafer and the photoresist layer;
patterning the photoresist layer to form a plurality of openings that respectively expose the metal layers;
filling a solder material into the openings to form a plurality of solder blocks; and removing the photoresist layer.

2. The process according to claim 1, after removing the photoresist layer, further comprising reflowing the solder blocks to form a plurality of bumps on the metal layers respectively.

3. The process according to claim 1, wherein the liquid comprises deionized water.

4. The process according to claim 1, wherein the liquid comprises chemical solvents.

5. The process according to claim 1, wherein forming the photoresist layer comprises attaching a dry film over the wafer.

6. The process according to claim 1, wherein the method of filling the solder material includes electroplating or printing.

7. A method for forming a photoresist layer on a substrate, comprising:
providing a liquid over the wafer; and
forming a photoresist layer over the wafer, wherein the photoresist layer reacts with the liquid to form a combination layer, wherein the combination layer has a fluidity larger than that of the photoresist layer.

8. The process according to claim 7, wherein forming the photoresist layer comprises attaching a dry film over the wafer.

9. The process according to claim 7, wherein the liquid comprises deionized water.

10. The process according to claim 7, wherein the liquid comprises chemical solvents.
